(19) United States
(12) Patent Application Publication
(10) Pub. No.: US 2026/0239895 A1
(43) Pub. Date: Aug. 13, 2026

(54) DEVICE FOR MANIPULATING QUBITS FOR A SEMICONDUCTOR SPIN QUBIT QUANTUM COMPUTER

(71) Applicants: RHEINISCH-WESTFÄLISCHE TECHNISCHE HOCHSCHULE (RWTH) AACHEN, Aachen (DE); FORSCHUNGSZENTRUM JÜLICH GMBH, Jülich (DE)

(72) Inventors: Matthias Künne, Aachen (DE); Lars Reiner Schreiber, Aachen (DE); Alexander Willmes, Aachen (DE); Jörg Hendrik Bluhm, Jülich (DE)

(21) Appl. No.: 19/153,355

(22) PCT Filed: Feb. 28, 2023
(86) PCT No.: PCT/EP2023/055059

§ 371 Date: Aug. 4, 2025

(51) Int. Cl. H10N 99/00; G06N 10/40; H10N 50/01; H10N 50/20

(52) U.S. Cl. CPC H10N 99/05; G06N 10/40; H10N 50/01; H10N 50/20

(57) ABSTRACT

A manipulation zone for a quantum processor comprising a plurality of gate electrodes arranged on a semiconductor heterostructure. The plurality of gate electrodes comprises a first finger gate assembly arranged at a first path in the semiconductor heterostructure and a second finger gate assembly arranged at a second path in the semiconductor heterostructure.

The first path and the second path meet at an interface. The first finger gate assembly and the second finger gate assembly are configured to be supplied with at least one voltage V, to move along the first path formed and/or the second path at least one qubit, and/or to manipulate a current spin state of the at least one qubit located at the first path and/or the second path.

### FIELD OF THE DISCLOSURE

The field of the present disclosure relates to the operation of quantum processors.

### BACKGROUND OF THE DISCLOSURE

Quantum processor architectures have to allow for scalability in order to achieve numbers of logical qubits sufficiently high to implement quantum computer chips that enable NISQ (noisy intermediate-scale quantum) era quantum computing or even universal quantum computing. In the case of spin qubit-based quantum computing, the qubits are arranged in a two-dimensional plane. A downside of this two-dimensional architecture is the so-called fan-out problem, i.e., spatial requirements of the wiring for the control lines of the quantum processor between the quantum processor and a classical control circuit. These spatial requirements scale faster with the number of qubits than the size of the hitherto proposed spin qubit-based quantum processor architectures.

Recently, an architecture for spin-qubits based on direct electron shuttling in Si/SiGe semiconductor heterostructures was proposed. The architecture includes shuttling paths along which qubits are transportable across, in principle, arbitrary distances such as of up to about 50 82 m. The shuttling paths allow to arrange components of the quantum processor, such as loading zones, readout zones, and manipulation zones, at a distance from each other, which lowers crosstalk. Providing shuttling paths also enables operations modes that require comparatively small operation frequencies and reduced local magnetic field gradients.

In these shuttling path-based architectures, high-fidelity shuttling is important for reliable computations. Such high-fidelity shuttling is compromised by, e.g., charge defects or low valley splitting along the shuttling path. The low valley splitting may lead to leakage out of the computational basis, e.g., two spin states, that is used for computation.

There is a need for identifying spots in the quantum processor, e.g., in the shuttling path or other components of the quantum processor, where the reliability of qubit handling is reduced, which ultimately impacts on the performance of the quantum processor.

### SUMMARY OF THE DISCLOSURE

A manipulation zone for a quantum processor comprises a plurality of gate electrodes arranged on a semiconductor heterostructure, wherein the plurality of gate electrodes comprises a first finger gate assembly arranged at a first path in the semiconductor heterostructure and a second finger gate assembly arranged at a second path in the semiconductor heterostructure. The first path and the second path meet at an interface. The first finger gate assembly and the second finger gate assembly are configured to be supplied with at least one voltage V, to move along the first path and/or the second path at least one qubit, and/or to manipulate a current spin state of the at least one qubit located at the first path and/or the second path.

The manipulation zone further comprises at least one magnet.

The at least one magnet may be arranged at the interface.

The at least one magnet may be arranged at a distance from the interface.

The semiconductor heterostructure may be made from semiconductor materials providing spin-orbit coupling.

At least one of the first finger gate assembly and the second finger gate assembly may comprise a plurality of electrode subsets.

Ones of the plurality of electrode subsets may are electrically disconnected from each other.

Ones of the plurality of electrode subsets may have a dielectric or insulating layer arranged between each other.

The manipulation zone may further comprise a top gate arranged above the first finger gate assembly and/or the second finger gate assembly.

The top gate is structured in a longitudinal direction.

A dielectric or insulating layer may be arranged between the semiconductor heterostructure and the plurality of gate electrodes.

Ones of the plurality of gate electrodes may have a dielectric or insulating layer arranged between each other.

The plurality of gate electrodes may be arranged on at least one surface of semiconductor heterostructure.

A system comprises a manipulation according the disclosure and a magnet providing an external magnetic field.

A method of manipulating at least one qubit located at a first path in a semiconductor heterostructure and/or a second path in the semiconductor heterostructure is disclosed. The first path and the second path meet at an interface. The semiconductor heterostructure comprises a plurality of gate electrodes arranged thereon. The method comprises the steps of providing an external magnetic field BO. The method comprises a further step of changing a current spin state of the at least one qubit by displacing the at least one qubit along the first path and/or the second path by means of an AC electric field applied to a gate electrode of the plurality of gate electrodes, or by irradiating the at least one qubit with electromagnetic radiation.

The method may further comprise adjusting a Rabi frequency or a resonance frequency relating to the changing of the current spin state of the at least one qubit.

The method may further comprise changing a tunnel barrier at the interface.

The method may further comprise changing a detuning between two qubits confined on either side of the interface.

### BRIEF DESCRIPTION OF THE DRAWINGS

FIG. 1 shows a schematic top view of a quantum processor.

FIG. 2 shows a schematic a top view of a unit cell of the quantum processor shown in FIG. 2.

FIG. 3A shows a top view of an aspect of a manipulation zone.

FIG. 3B shows a longitudinal cross-section of a further aspect the manipulation zone.

FIG. 3C shows a longitudinal cross-section of a further aspect of the manipulation zone.

FIG. 3D shows a longitudinal cross-section of a further aspect of the manipulation zone.

FIG. 3E shows a line cut of a temporal sequence of a simulation of an evolution of a potential energy landscape at the interface of a manipulation zone.

FIG. 4 shows in the upper panel an effect on a shuttling voltage of applying adjustment voltage for changing a confinement of a qubit. FIG. 4 shows in the lower panel an effect on a shuttling voltage of applying adjustment voltage for shifting a confinement a qubit.

### DETAILED DESCRIPTION

The present disclosure relates to a method of operating a quantum processor as well as to a method of manufacturing a quantum processor.

The quantum processor may operate based on spin qubits. A spin qubit is a two-level quantum system of a spin degree of freedom. An example of a spin qubit is the two-level quantum system of the spin of an electron confined in a quantum dot. Another example is a hole spin qubit. Furthermore, a group of electrons, for example two or three electrons, may be used to implement a spin qubit, such as an S-TO singlet-triplet system of two electrons in a quantum double-dot.

The method of the present disclosure is applicable to any type of electrically controllable spin qubit implemented in a semiconductor heterostructure 12. Using an electron-based spin qubit involves bringing the electron spin into a known state. To this end, the state of the electron is initialized. In one aspect, a selected qubit is associated with the same electron throughout the performing of a quantum algorithm. In another aspect, a qubit implemented by a first electron may be initialized and, subsequently to an operation on the qubit, the qubit may be implemented by means of a second electron. In a further aspect, there are situations in which it is impossible to tell whether the qubit is implemented by the first electron or by the second electron, without compromising the performing of quantum algorithms. Likewise, the method of the present disclosure may be applied on any type of hole spin qubit.

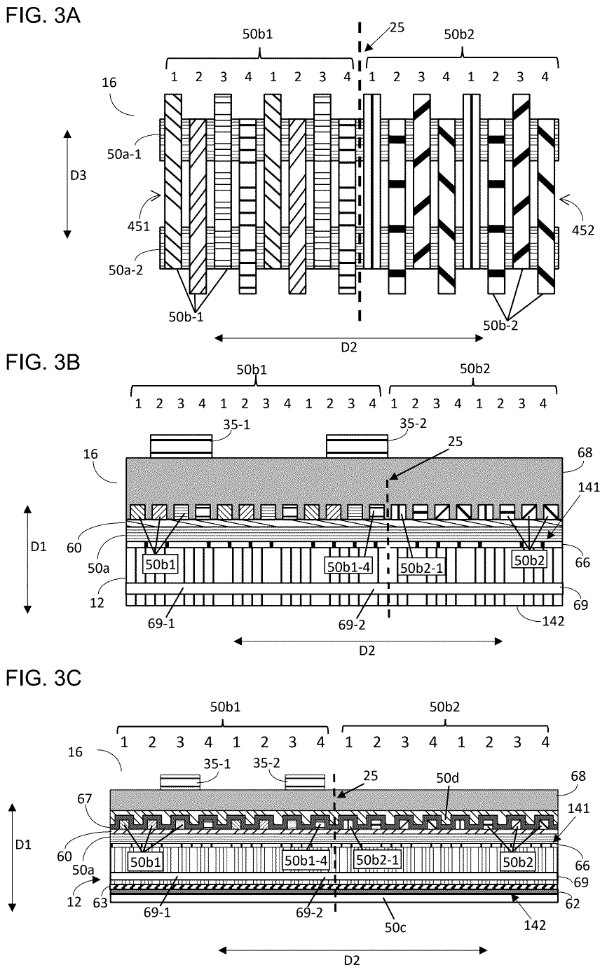

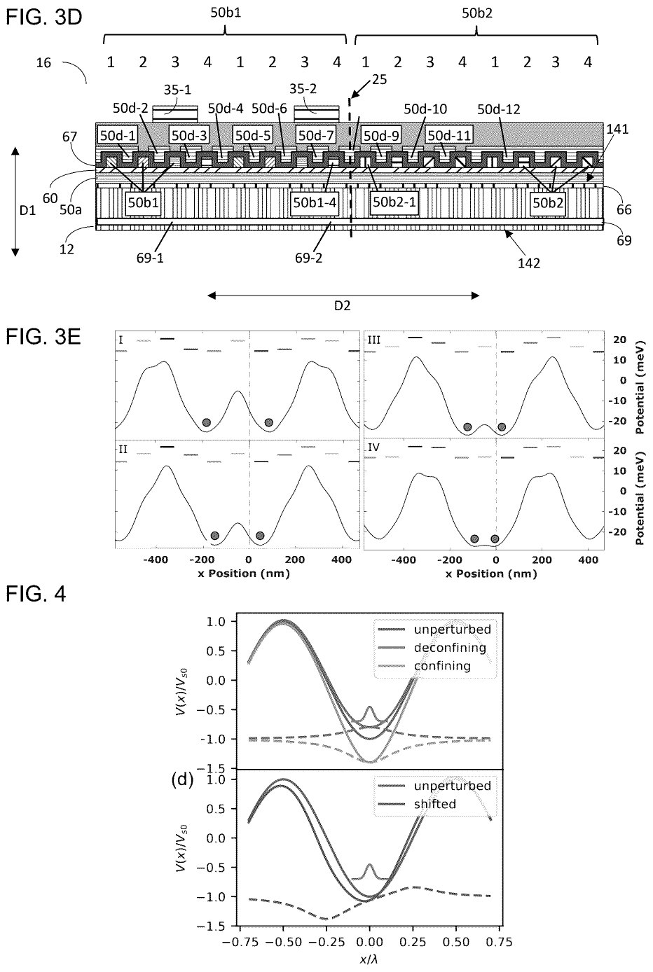

Using semiconductor materials to form a structure, e.g., a semiconductor heterostructure, for implementing the quantum processor facilitates manufacturing due to easy handling and low costs of the materials, such as in the case of silicon. There are established technologies for using silicon in computing hardware. A two-dimensional electron gas (2 DEG) or a two-dimensional hole gas (2 DHG) is confinable within the structure formed from the semiconductor materials in a quantum well 69 (see below and FIG. 3B-3D). The 2 DEG or the 2 DHG may further be confined based on electrical potentials. The electric potentials may be static electric potentials or non-static electric potentials. The electrical potentials may form at least one quantum dot, in which at least one electron or hole of the 2 DEG or 2 DHG is trappable or confinable. The spin of the trapped (confined) at least one electron or hole is usable to implement spin qubits. Moving the electrical potentials results in moving the at least one quantum dot. The moving of the at least one quantum dot enables moving the trapped (confined) at least one electron/hole as well as the qubits associated with the trapped (confined) at least one electrons/holes. Altering a strength of the electrical potentials alters the degree of confinement of the trapped (confined) at least one electron or hole.

The quantum processor may comprise a plurality of unit cells. A unit cell of the plurality of unit cells comprises components that perform at least one action or operation on one or more qubits located in the unit cell. The at least one action on the one or more qubits includes: loading of the one or more qubits into the unit cell; unloading of the one or more qubits from the unit cell; moving (shuttling) the one or more qubits within the unit cell or beyond the unit cell (i.e., to another one of the unit cell of the quantum processor); manipulating a quantum state of the one or more qubits; and readout of the quantum state of the one or more qubits. The manipulating of the one or more qubits comprises manipulating a single qubit or manipulating two qubits. The manipulating of the single qubit comprises rotating the spin of the single qubit, e.g., for driving transitions between a plurality of spin states. The plurality of spin states may comprise, e.g., a spin-up state and a spin-down state. The manipulating of the two qubits comprises implementing a CPHASE gate, a CNOT gate, and/or a SWAP gate.

In one aspect, several actions performed on the one or more qubits by the components of the unit cell may be performed one after another as a sequence of actions. For example, two actions may be performed one after another. In another aspect, the several actions performed on the one or more qubits by the components of the unit cell may be performed in parallel. For example, the two actions may be performed in parallel.

In one aspect, the several actions on the one or more qubits may be performed within a single one of the plurality of the unit cells or across several ones of the plurality of unit cells.

In one aspect, the several actions may be performed as part of determining a gate fidelity (see below for more details). For example, the determining of the gate fidelity may comprise performing the sequence of actions on the one or more qubits.

In another aspect, the several actions may be performed as part of performing an algorithm. For example, the performing of the algorithm may comprise performing the sequence of actions on the one or more qubits.

The components are arranged within the unit cell. Some of the components are connected with each other. The components and the connections of the components thus form a layout or structure of the unit cell. Ones of the plurality of unit cells may have substantially the same structure, in which the same components are arranged and connected with each other in substantially the same way. Other ones of the plurality of unit cells may have differing structures, in which the components and/or the connections of the components differ.

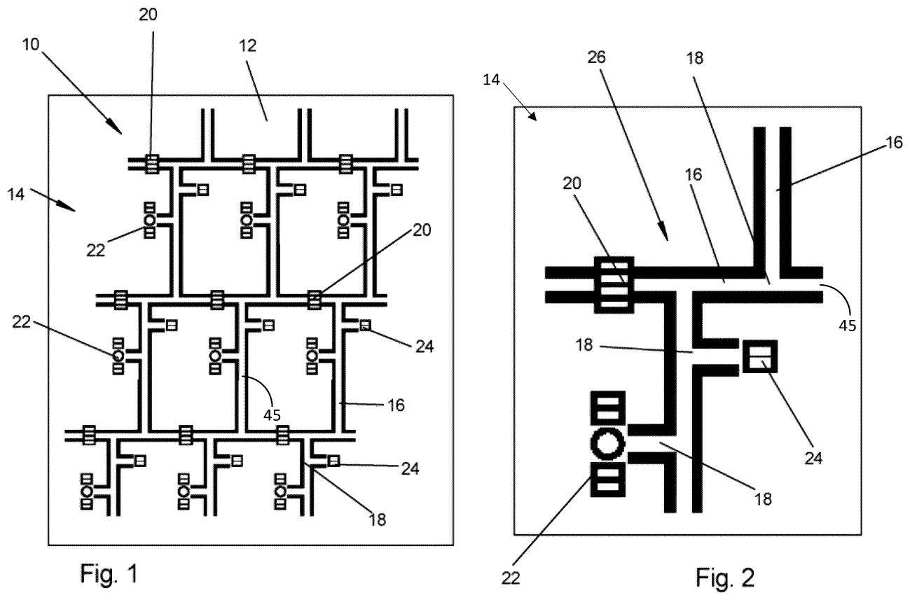

Aspects of the quantum processor are disclosed in international patent application no. WO 2021/052541 A1, the disclosure of which is incorporated herein by reference in its entirety. In this aspect, shown in FIGS. 1 and 2, the quantum processor 10 comprises the semiconductor heterostructure 12. The semiconductor heterostructure 12 comprises several layers of differing material composition. The semiconductor heterostructure 12 may be a Si/SiGe or GaAs/AlGaAs heterostructure, however, the use of other materials in which a two-dimensional electron gas (2 DEG) or a two-dimensional hole gas (2 DHG) can be formed, such as Si-MOS or Ge/SiGe, is possible. The semiconductor heterostructure may be undoped and/or strained. The semiconductor heterostructure 12 may serve as a substrate of the quantum processor 10. The semiconductor heterostructure 12 may comprise the 2 DEG. The 2 DEG or the 2 DHG may be arranged or located in the quantum well 69 (see FIG. 3B-D). The one or more qubits may be arranged in the quantum well 69. The one or more qubits may be arranged in the at least one quantum dot formed in the quantum well 69. The one or more qubits may be generated from the 2 DEG.

In one aspect, the semiconductor heterostructure 12 may further comprise a silicon cap 64, on which a dielectric or insulating layer 66 is arranged(not shown) The gate electrodes 50a, 50b, 50d may be arranged on top of and/or above the dielectric or insulating layer 66.

In a further aspect, the semiconductor heterostructure 12 may further comprise a layer of strained silicon 63 (see FIG. 3C). In yet a further aspect, the semiconductor heterostructure 12 may further comprise a layer of silicon dioxide 62 (see FIG. 3C).

In the aspect of the quantum processor 10 shown in FIGS. 1 and 2, the components 16, 18, 20, 22, 24 are provided on at least one surface 14 of the semiconductor heterostructure 12. As can be seen in FIG. 1, the shown aspect of the quantum processor 10 comprises one or more of each of the components 16, 18, 20, 22, 24. In another aspect, the quantum processor 10 may comprise one or more of only some of the component 16, 18, 20, 22, 24.

The quantum processor 10 shown in FIGS. 1 and 2 is a substantially two-dimensional device, as defined by the at least one surface 14. A third dimension of the quantum processor 10 is defined by a thickness of the semiconductor structure 12 and a thickness of the components 16, 18, 20, 22, 24.

The plurality of unit cells of the quantum processor 10 comprises several of the unit cell 26 (shown in FIG. 2). In the aspect shown in FIG. 2, the unit cell 26 comprises the components 16, 18, 20, 22, 24. In another aspect of the disclosure, the unit cell 26 comprises merely some of the components 16, 18, 20, 22, 24. In yet a further aspect, the unit cell 26 may comprise more than one of at least one of the components 16, 18, 20, 22, 24.

The components 16, 18, 20, 22, 24 comprise a plurality of gate electrodes 50 (see FIGS. 3A and 3B) arranged on at least one surface 14 of the semiconductor heterostructure 12. The plurality of gate electrodes 50 may be arranged to define within the associated one of the components 16, 18, 20, 22, 24 at least one path 45 (see FIG. 3A) within the quantum well 69 along which the one or more qubits may be moved (shuttled).

In FIGS. 1 and 2, the at least one path 45 is shown to substantially be directed in two directions on the surface 14 that are substantially perpendicular to one another, resulting in structure of a plurality of paths 45 that is grid-like. The plurality of paths 45 connect the components 16, 18, 20, 22, 24.

The plurality of gate electrodes 50 may further be arranged to move (shuttle) the one or more qubits along the at least one path 45. The movement (shuttling) may occur in either one of the two directions (back and forth) along the at least one path 45. The plurality of gate electrodes 50 may further be arranged for performing the at least one action on the one or more qubits, performed by the components 16, 18, 20, 22, 24.

The plurality of gate electrodes 50 may be provided with voltages. The plurality of gate electrodes 50 may be made of metal. The plurality of gate electrodes 50 may be superconducting. The voltages may serve one or more purposes, such as defining the at least one path 45, moving (shuttling) the one or more qubits, and/or implementing the at least one action on the one or more qubits. The voltages may comprise DC (direct current) voltages and AC (alternating current) voltages. The voltages may comprise one or more stationary voltages and one or more non-stationary voltages. The voltages may be applied by means of DC lines, AC lines, and/or bias tees.

One or more of the components 16, 18, 20, 22, 24 may further comprise at least one magnet 35, such as a micromagnet (see FIG. 3B-3D). The at least one micromagnet 35 may be placed on top of the component 16, 18, 20, 22, 24. The at least one micromagnet 35 provides a magnetic field. The magnetic field may have a zero gradient or a non-zero gradient. The at least one magnet 35 may have a distance from the quantum well 69 of 150 nm. The at least one magnet may have dimensions of 400 nm×200 nm×20 nm. The at least one magnet 35 may be arranged on a dielectric or insulating layer 68 (see FIGS. 3B-3D). The dielectric or insulating layer 68 may be arranged on the conveyor gates 50b (see FIG. 3B) or on a top gate 50d (see FIGS. 3C and 3D and below).

An external magnetic field Bo splits the plurality of spin states (e.g., the spin-up state and the spin-down state) used as a computational basis for the one or more qubits into spin-dependent energy levels (Zeeman splitting). The external magnetic field Bo may be provided by an external magnet, e.g., an electromagnet (not shown), that is placed in the vicinity of the quantum processor 10. The quantum processor 10 may at least partially be placed in the external magnetic field Bo provided by the external magnet.

The one or more components 16, 18, 20, 22, 24 may further comprise means for providing electromagnetic radiation, e.g., microwaves, for manipulating the quantum state of the one or more qubits, e.g., switching the spins of the one or more qubits between the plurality of spin states. The electromagnetic radiation may be provided by means of one or more of the gate electrodes 50b. The spin of a qubit may be switched between, e.g., the spin-up and the spin-down state, or vice versa, by means of the electromagnetic radiation based on electron spin resonance (ESR). The frequency of the electromagnetic radiation may equal the energy difference of the separated energy levels. ESR provides a further way of manipulating the quantum state of the one or more qubits. The microwaves may have a frequency in the range of several hundred MHz to several hundred GHz. In one aspect, the frequency lies in the range of 9-10 GHz, but is not limited thereto.

Providing an inhomogeneous magnetic field, i.e., having a non-zero gradient, enables manipulating the quantum state of the one or more qubits, e.g., rotating the spin of the qubit. The rotating enables driving transitions between the plurality of spin states by means of a displacement of the one or more qubits in the inhomogeneous magnetic field based on, e.g., an AC electric field. The AC electric field may be provided by means of one or more of the gate electrodes 50b. This effect is called electric dipole spin resonance (EDSR). The displacement may make the qubit oscillate between the plurality of spin states (e.g., the spin states forming the computational basis such as the spin-up state and the spin-down state). For example, the qubit may oscillate such that the spin-up state can be switched to the spin-down state, and vice versa.

Alternatively, the EDSR may be achieved in one of the semiconductor heterostructure 12 in which spin-orbit coupling is present. The semiconductor heterostructure 12 may be made from semiconductor materials that provide the spin-orbit coupling.

The plurality of gate electrodes 50 may be provided as one or more of gate electrode assemblies 50a, 50b, 50c, 50d. The plurality of gate electrodes 50 may comprise one or more laterally positioning gate electrodes (also termed “screening gates”) 50a (see FIG. 3A) arranged to define and/or modify a lateral position of a trajectory in the quantum well 69 and/or at the at least one path 45 for moving (shuttling) the one or more qubits within the unit cell or beyond the unit cell. The trajectory may be a trajectory of one or more potential wells (further described below), in which the one or more qubits are arrangeable. The one or more potential wells may thus be one or more travelling potential wells. The trajectory of the one or more potential wells may thus correspond to a trajectory of the one or more qubits arranged at the least one path 45. Thus, the lateral position of the trajectory may correspond to a lateral position of the one or more potential wells and/or of the one or more qubits. Arranging the one or more qubits at the least one path 45 is to be understood to mean that the one or more qubits are arranged within the quantum well 69.

The plurality of gate electrodes 50 may further comprise one or more shuttling gate electrodes (also termed “conveyor gates” or “finger gates” or “clavier gates”) 50b (see FIG. 3A) arranged to move (shuttle) the one or more qubits along the at least one path 45 for moving (shuttling) the one or more qubits within the unit cell or beyond the unit cell.

The plurality of gate electrodes 50 may further comprise at least one vertically positioning gate electrode (also termed “back gate”) 50c arranged to define and/or modify a vertical position of the trajectory 80 (see FIG. 3C) in the quantum well 69 and/or at the at least one path 45 for moving (shuttling) the one or more qubits within the unit cell or beyond the unit cell. The vertical position of the trajectory 80 may correspond to a vertical position of the one or more potential wells and/or of the one or more qubits.

The plurality of gate electrodes 50 may further comprise qubit-handling gate electrodes arranged for performing the at least one action on the one or more qubits. The qubit-handling electrodes include plunger gates and barrier gates. The plunger gates may be used to control the occupation of a quantum dot, to control a detuning in a double quantum dot, and/or to perform an exchange of two qubits. The barrier gates may be used to form a potential double-well and/or to control the tunnel barrier in a double quantum dot.

The plurality of gate electrodes 50 may be arranged on the at least one surface 14 of the semiconductor heterostructure 12. The plurality of gate electrodes 50 may be arranged in layers that are separated by an insulating or dielectric layer 60 and the insulating or dielectric layer 66 (see FIG. 3B-3D). In one aspect, the layers may be arranged in a direction substantially perpendicular to the direction of the at least one path 45.

One or more of the insulating or dielectric layer 60, the insulating and dielectric layer 66, and/or the insulating or dielectric layer 67 may be planarized. A method of manufacturing the shuttling element 16 may comprise the step of planarizing one or more of the insulating or dielectric layer 60, the insulating and dielectric layer 66, and/or the insulating or dielectric layer 67. The insulating or dielectric layer 60 may be planarized during manufacturing before arranging the conveyor gates 50b on the insulating or dielectric layer 60. The planarizing facilitates using processes such as electron ray epitaxy, Deep UV, and/or spacer lithography. The planarizing reduces the thickness of one or more of the dielectric or insulating layers 60, 66, 67. For instance, the insulating or dielectric layers 66 and/or 60 may be planarized before manufacturing of the conveyor gates 50b to reduce the thickness of the insulating or dielectric layer 66 and/or 60, respectively. After planarization, the insulating or dielectric layers 66 and/or 60 are tightly placed on the semiconductor heterostructure 12. Planarizing the insulating or dielectric layers 66 and/or 60 results in the thickness of the insulating or dielectric layers 66 and/or 60 being reduced between the at least one path 45 and the conveyor gates 50b. In one aspect, the thickness of the insulating or dielectric layer 60 is required to cover a top surface and sides of the screening gates 50a.

The component 16 serves to move (shuttle) the one or more quantum dots in the semiconductor heterostructure 12 for moving (shuttling) the one or more qubits within the unit cell or beyond the unit cell. The component 16 is also termed “shuttling lane”. Aspects of the shuttling lane 16 are disclosed in international patent application no. WO 2021/052531 A1, the disclosure of which is incorporated herein by reference in its entirety.

The component 18 provides a junction at which the one or more quantum dots may be diverted into at least one branch (at least one second one of the at least one path 45) that branches off of the at least one path 45 for moving (shuttling) the one or more qubits within the unit cell or beyond the unit cell. The component 18 is also termed “T-junction”. The at least one path 45 and the at least one branch of the T-junction 18 may be arranged perpendicular or non-perpendicular to one another. In one aspect, the at least one path 45 and the at least one branch of the T-junction 18 may substantially form a T-shape. Aspects of the T-junction 16 are disclosed in international patent application no. WO 2021/052539 A1, the disclosure of which is incorporated herein by reference in its entirety.

The component 20 is provided for manipulating qubits in quantum dots. The component 20 is also termed “manipulation zone”. The manipulation zone 20 enables manipulating one or more current spin states of the one or more qubits. Any one qubit has a current spin state. In one aspect, the plurality of spin states may comprise the current spin state. In another aspect, the current spin state may be a linear combination of the plurality of spin states. During the manipulating, the one or more current spin states may be changed. Aspects of the manipulation zone 20 are disclosed in WO 2021/052537 A1, the disclosure of which is incorporated herein by reference in its entirety.

The component 22 serves to initialize the one or more spin states of the one or more qubits. When the one or more spin states have been initialized, any one of the one or more current spin states is equal to one of the plurality of spin states. After initialization, the one or more current spin states may remain unchanged during a relaxation time. The relaxation time describes transitions between the spin-up state and the spin-down state due to interactions with the environment, such as the lattice of the semiconductor heterostructure 12. The component 22 is also termed “initialization zone”. Aspects of the initialization zone 22 are disclosed in WO 2021/052538 A1, the disclosure of which is incorporated herein by reference in its entirety.

The component 24 serves to read out the one or more spin states of the one or more qubits. When the one or more spin states have been read out, any one of the one or more current spin states prior to readout is known. The component 24 is also termed “readout zone”. Aspects of the readout zone 24 are disclosed in WO 2021/052536 A1, the disclosure of which is incorporated herein by reference in its entirety.

In one aspect of the disclosure, the initialization zone 22 and the readout zone 24 are the same component.

The quantum processor 10 is operated to perform algorithms, such as quantum algorithms. The performing of the algorithms includes performing the sequence of actions on the one or more qubits, as explained above. The at least one action is performed by the components 16, 18, 20, 22, 24 of the unit cells 26.

The operating of the quantum processor 10 involves controlling the at least one action performed by the components 16, 18, 20, 22, 24. In one aspect of the disclosure, the at least one action is controlled by applying the voltages to the plurality of gate electrodes 50. The voltages may be set and/or adjusted to increase a fidelity F of the at least one action or of the sequence of actions. The fidelity F is a measure of how reliably the at least one action or the sequence of actions results in the outcome that is expected based on the design of the quantum processor 10 and on the voltages applied to the plurality of gate electrodes 50. To determine the fidelity F, the at least one action or the sequence of actions is repeated; subsequently the proportion of the repetitions is determined in which the actual outcome equals the expected outcome. The actual outcome includes the one or more current spin states that have been read out at the readout zone 24 after the at least one action or the sequence of actions. The expected outcome includes the one or more current spin states that are, based on known fidelities of the components 16, 18, 20, 22, 24 and/or the relaxation time of the one or more qubits, expected to be read out at the readout zone 24 after the at least one action or the sequence of actions.

For example, the at least one action may comprise the moving (shuttling) of the one or more qubits along the at least one path 45 of the shuttling lane 16, e.g., to the manipulation 20, and the manipulating the quantum state of the one or more qubits in the manipulation zone 20. In this case, the fidelity F of performing the at least one action is a combination, i.e., the product, of a shuttling fidelity F_{S} and a manipulation fidelity F_{M}, i.e., F=F_{S}×F_{M}. The manipulation fidelity F_{M}, relating to the manipulation zone 20, may then be calculated by dividing the fidelity F by the shuttling fidelity. The manipulation fidelity F_{M} is understood to be a probability that the one or more current spin states of the one or more qubits are changed as expected during the manipulating. The shuttling fidelity F_{S} may be determined, for example, by repeatedly performing the sequence of actions: initialization of a qubit, moving (shuttling) of the qubit, and readout of the qubit; followed by determining whether the initialized spin state of the one or more qubits are equal to the the one or more current spin states after shuttling and prior to readout; and finally calculating the proportion of the repetitions in which the one or more spin states were unaltered. The manipulation fidelity FM may be determined, for example, by repeatedly performing the sequence of actions: initialization of the one or more qubits, moving (shuttling) of the one or more qubits, manipulation of the one or more qubits, and readout of the one or more qubits; followed by determining whether the one or more initialized current spin states of the one or more qubits are changed as expected; calculating the proportion of the repetitions in which the one or more current spin state are changed as expected, dividing the result by the shuttling fidelity Fs.

The fidelity F may further be a gate fidelity. The gate fidelity F is a measure of how closely the outcome of a gate operation (i.e., the sequence of actions by means of the components 16, 18, 20, 22, 24 on the one or more qubits that are associated with a gate the quantum processor 10 is designed to implement) matches the expected, e.g., theoretical, outcome based on the design of the quantum processor 10 and the components 16, 18, 20 22, 24. The gate fidelity F may be determined by randomized benchmarking.

As an example, increasing the manipulation fidelity F_{M} of one or more qubits, e.g., the single qubit or the two qubits, at the manipulation zone 20 will be described. FIG. 3A shows an aspect of the manipulation zone 20. The manipulation zone 20 comprises the screening gates 50a and the conveyor gates 50b arranged on the at least one surface 14 of the semiconductor heterostructure 12. In the aspect shown in FIG. 3A, the at least one surface 14 comprises a top surface 141 of the semiconductor heterostructure 12. In the aspect shown in FIG. 3B, the top surface 141 may be a top surface of dielectric or insulating layer 66 (further described below).

The screening gates 50a are arranged to extend on either side of a first path 451 and a second path 452 as screening gates 50a-1 and 50a-2 (see also FIG. 3A). In one aspect, as shown in FIGS. 3A-3C, the screening gates 50a-1 and 50a-2 may extend continuously along the at least one path 45. In another aspect, the screening gates 50a-1 and 50a-2 may be interrupted. The screening gates 50a-1 and 50a-2 may be spaced apart by approximately 200 nm. The screening gates 50a may be made from metal and may be manufactured by embedding the metal in the semiconductor heterostructure 12 or by local implantation of the semiconductor heterostructure 12. The screening gates 50a may be embedded in the dielectric or insulating layer 66 and/or in the dielectric or insulating layer 60.

The dielectric or insulating layer 66 and/or in the dielectric or insulating layer 60 may be structured in the lateral direction D3. In one aspect, the dielectric or insulating layer 66 and/or in the dielectric or insulating layer 60 may be provided as two separate portions (not shown), the separate portions enveloping the two screening gates 50a-1 and 50a-2, and the semiconductor heterostructure 12 extending into a space (not shown) between the two portions along the lateral (or transverse direction) D3. The semiconductor heterostructure 12 thus may form a ridge (not shown) in the space between the two portions of the dielectric or insulating layer 66 and/or in the dielectric or insulating layer 60.

The conveyor gates 50b may extend transversely across the first path 451 and/or the second path 452 (as shown in FIG. 3A). For example, the conveyor gates 50b may extend in a lateral direction D3. The conveyor gates or finger gates 50b are arranged along the at least one path 45.

In the aspect shown in FIG. 3A, the conveyor gates 50b have a first conveyor gate assembly 50b1 and a second conveyor gate assembly 50b2. In FIGS. 3A-D, the first conveyor gate assembly 50b1 and second conveyor gate assembly 50b2 are indicated by the braces at the top of the drawings. In addition, three electrodes belonging to the first conveyor gate assembly 50b1 and three electrodes belonging to the second conveyor gate assembly 50b2 are indicated in FIGS. 3A-D for the sake of clarity. The first conveyor gate assembly 50b1 and/or the second conveyor gate assembly 50b2 is arranged to extend transversely across at least part of the first path 451 and/or the second path 452, respectively. The first conveyor gate assembly 50b1 and the second conveyor gate assembly 50b2 are arranged at an interface 25 such that the first path 451 and the second path 452 meet at the interface 25 (see FIGS. 3A and 3B).

The first path 451 and the second path 452 meet at the interface 25 such that a first qubit, trapped in first quantum dot and shuttled along the first path 451 to the interface 25, and a second qubit, trapped in a second quantum dot and shuttled along the second path 452, can undergo at least one two-qubit action (or operation) at the interface 25. The one or more potential wells may comprise one or more first potential wells. The first qubit may be shuttled (moved) along the first path 451 by the one or more first travelling potential wells. The one or more first travelling potential wells may be generated by applying the voltages to the first conveyor gate assembly 50b1. Likewise, the one or more potential wells may comprise one or more second potential wells. The second qubit may be shuttled (moved) along the second path 452 by the one or more second travelling potential wells. The one or more second travelling potential wells may be generated by applying the voltages to the second conveyor gate assembly 50b2.

The at least one two-qubit action (or operation) at the interface 25 are enabled by forming at the interface ones of the one or more potential wells that are stationary (“one or more stationary potential wells”). The one or more stationary potential wells may comprise at least one first stationary potential well and at least one second stationary potential well.

The at least one first stationary potential well may be arranged at the interface 25. For instance, the at least one first stationary potential well may be adjacent to the interface. The at least one first stationary potential well may be generated by the first conveyor gate assembly 50b1. Likewise, the at least one second stationary potential well may be arranged at the interface 25. For instance, the at least one second stationary potential well may be adjacent to the interface. The at least one second stationary potential well may be generated by the second conveyor gate assembly 50b2.

The first qubit may be trapped in the at least one first stationary potential well. Likewise, the second qubit may be trapped in the at least one second stationary potential well. When the at least one first stationary potential well and the at least one second stationary potential are arranged at the interface 25, the first qubit trapped in the least one first stationary potential well and the second qubit trapped in the at least one second potential well may undergo the at least one two-qubit action (or two-qubit operation).

For example, at the interface 25 a potential barrier may be formed by means of the first conveyor gate assembly 50b1 and the second conveyor gate assembly 50b2 between the at least one first stationary potential well and the at least one second stationary potential well. For example, the potential barrier may be formed by an electrode subset 50b1-4 (described below) of the first conveyor gate assembly 50b1 and an electrode subset 50b2-1 (described below) of the second conveyor gate assembly 50b2.

A lowering/raising of the potential barrier may increase/decrease a tunnel coupling across the potential barrier (also referred to as “tunnel barrier”). In one aspect, the height of the potential barrier may be adjusted by pulsing, e.g., by non-adiabatic pulsing. The confinement in the at least one first stationary potential well and in the at least one second stationary potential well may or may not be different relative to one another, which is referred to as a detuning. The detuning may be zero or non-zero. The detuning may be generated by means of the first conveyor gate assembly 50b1 and the second conveyor gate assembly 50b2. For example, the detuning may be generated by an electrode subset 50b1-3 (described below) of the first conveyor gate assembly 50b1 and an electrode subset 50b2-2 (described below) of the second conveyor gate assembly 50b2.

The tunnel coupling and the detuning determine an exchange coupling J between the first qubit trapped in the first stationary potential well and the second qubit trapped in the second stationary potential well. The exchange coupling J enables the first qubit and/or the second qubit to tunnel through the potential barrier into the at least one first stationary well or the at least one second stationary potential well.

The first conveyor gate assembly 50b1 has electrode subsets 50b1-1, 50b1-2, 50b1-3, 50b1-4 (indicated in FIGS. 3A-D by indices 1, 2, 3, 4 above the conveyor gates of the corresponding electrode subset). The ones of the conveyor gates 50b that belong to one of the electrode subsets 50b1-1, 50b1-2, 50b1-3, 50b1-4 are marked with the same index at the top of FIGS. 3A-3D, i.e., the index 1, 2, 3, or 4. The number of electrode subsets 50b1-1, 50b1-2, 50b1-3, 50b1-4 shown in FIG. 3A is four. Likewise, the second conveyor gate assembly 50b2 has electrode subsets 50b2-1, 50b2-2, 50b2-3, 50b2-4 (indicated in FIG. 3A-D by indices 1, 2, 3, 4 above the conveyor gates of the corresponding subset). The ones of the conveyor gates 50b that belong to one of the electrode subsets 50b2-1, 50b2-2, 50b2-3, 50b2-4 are marked with the same index at the top of FIGS. 3A-3D, i.e., the index 1, 2, 3, or 4. As shown in FIGS. 3A-3D, the interface 25 is located at one electrode of the electrode subset 50b1-4 of the first conveyor gate assembly 50b1 and at one electrode of the electrode subset 50b2-1 of the second conveyor gate assembly 50b2. The number of electrode subsets 50b2-1, 50b2-2, 50b2-3, 50b2-4 shown in FIG. 3A is four. However, the number of the electrode subsets of the first conveyor gate assembly 50b1 and/or the second conveyor gate assembly 50b2 may differ from this example and be, e.g., three or five. Any number of the electrode subsets of the conveyor gates 50b may be chosen, as long as the one or more travelling potential wells for moving (shuttling) a qubit (see below) can be generated. The one or more travelling potential wells provide the confinement to trap an electron or hole, the strength of which is sufficiently strong to overcome disorder during moving (shuttling) in the quantum well 69, and the height of which provide barriers between adjacent potential well to suppress tunnelling. The trapped one or more electrons or holes adiabatically follow a sufficiently slow translation of the potential. The disorder is due to one or more of defects at boundaries of the layers of the semiconductor heterostructure 12, defects within the layers of the heterostructure 12, and/or defects within the dielectric layers 60, 66 and/or 67. The defects at the boundaries of the layers of the semiconductor heterostructure 12 include charge defects at interfaces between layers made from semiconductor materials and the dielectric or insulating layers 60 and/or 66. These charge defects are randomly distributed, e.g., at the interfaces. A density of the charge defects was set to 5E10/cm². Transitions to excited orbital states of the electron confined in the one or more travelling potential wells are caused by the disorder. In a moving frame of the one or more travelling potential wells, the disorder that quasi-statically fluctuates turns into dynamic noise that couples the orbital levels. Setting the shuttling speed is set to v=10 m/s results in a reduced orbital excitation rate and a below-threshold phase error.

In one aspect, the conveyor gates 50b may be arranged at the at least one path 45 in a manner, in which juxtaposed ones of the conveyor gates 50b extend differently far in the lateral (or transverse) direction D3 (as shown in FIG. 3A). In another aspect the conveyor gates 50b may extend equally far in the lateral (or transverse direction) D3.

The conveyor gates 50b may be arranged in a substantially equidistant manner with a substantially constant conveyor gate spacing between any two neighboring conveyor gates 50b. If a conveyor gate width, i.e., an extension of the conveyor gates 50b in the longitudinal direction D3, of the conveyor gates 50b is substantially constant, also a conveyor gate pitch, which is the sum of the conveyor gate spacing and the conveyor gate width, is substantially constant. In one aspect of the disclosure, the conveyor gate pitch may be approximately 80 nm. The conveyor gates 50b may be arranged in a periodic manner. In one aspect, the conveyor gates 50b of any one of the electrode subsets 50b-1, 50b-2, 50b-3, 50b-4 may be arranged in a substantially equidistant manner from each other based on a spatial period of the periodically arranged conveyor gates. In another aspect, any two conveyor gates 50b belonging to any selected one of the electrode subsets 50b-1, 50b-2, 50b-3, 50b-4 have one conveyor gate of each of the other non-selected ones of the electrode subsets arranged therebetween. The periodical arrangement of the conveyor gates 50b facilitates industrial manufacturing of the shuttling path 16.

The conveyor gates belonging to any one of the electrode subsets 50b1-1, 50b1-2, 50b1-3, 50b1-4, 50b2-1, 50b2-2, 50b2-3, 50b2-4, shown in FIG. 3A, are electrically connected to each other by an electrical connection (not shown). The conveyor gates of any selected electrode subset from the electrode subsets 50b1-1, 50b1-2, 50b1-3, 50b1-4, 50b2-1, 50b2-2, 50b2-3, 50b2-4 are electrically disconnected from (or not electrically connected to) the conveyor gates of the other ones (i.e., the corresponding non-selected ones) of the electrode subsets 50b1-1, 50b1-2, 50b1-3, 50b1-4, 50b2-1, 50b2-2, 50b2-3, 50b2-4. The electrical connection may be provided by a metal strip arranged parallel to the screening gates 50a. The electrode subsets of the conveyor gates 50b1 and/or 50b2 with indices 1 and 3 may have the electrical connection on one side of the at least one path 45 (above the at least one path 45 as seen in FIG. 3A). The electrode subsets of the conveyor gates 50b with indices 2 and 4 may have the electrical connection on the other side of the at least one path 45 (below the at least one path 45 as seen in FIG. 3A). In one aspect of the disclosure, the electrode subsets 50b-1, 50b-2, 50b-3, 50b-4 may be arranged at different levels in the stacking direction D1. For example, the metal strip connecting the conveyor gates of the electrode subset 50b-1 may be arranged on one side of the at least one path 45 at a higher level in the stacking direction D1 than the metal strip connecting the conveyor gates of the electrode subset 50b-3; and the metal strip connecting the conveyor gates of the electrode subset 50b-2 may be arranged on the other side of the at least one path 45 at a higher level in the stacking direction D1 than the metal strip connecting the conveyor gates of the electrode subset 50b-4. The electrode subsets 50b-1, 50b-2, 50b-3, 50b-4 may each be arranged at the level at which the corresponding metal strip is arranged. In another aspect, the metal strips may be all arranged on one side of the at least one path 45. In a further aspect, ones of the metal strips connecting the conveyor gates of the electrode subsets 50b-1, 50b-2, 50b-3, 50b-4 may be electrically connected to the conveyor gates of the corresponding electrode subset by vias; and the conveyor gates of the electrode subsets 50b-1, 50b-2, 50b-3, 50b-4 may be arranged at substantially one level in the stacking direction D1.

The electrical connection of the conveyor gates of any one of the electrode subsets 50b1-1, 50b1-2, 50b1-3, 50b1-4, 50b2-1, 50b2-2, 50b2-3, 50b2-4 enables providing a single voltage to the corresponding electrode subset of conveyor gates of the first conveyor gate assembly 50b1 or the second conveyor gate assembly 50b2. In other words, the number of voltage signals applied to the conveyor gates 50b is given by the number of electrode subsets chosen. As a result, the number voltage signals applied to screening gates 50a and the conveyor gates 50b is independent of a length of the shuttling element 16. In the example shown in FIGS. 3A and 3B, the number of electrode subsets is four. However, the number may be smaller or larger than four. For example, using three electrode subsets may achieve moving the one or more qubits by means of the travelling potential well.

The at least one magnet 35 provides a magnetic field (not shown). The magnetic field may be an inhomogeneous magnetic field. The magnetic field of the magnetic field provided by the at least one magnet 35 may have a non-zero magnetic field strength at the quantum well 69. The magnetic field may have a longitudinal component of non-zero longitudinal magnetic field strength at the quantum well 69 along a shuttling direction (or longitudinal direction) D2. The magnetic field may have a transverse component of non-zero transverse magnetic field strength at the quantum well 69 along the lateral (or transverse) direction D3.

Furthermore, the magnetic field of the at least one magnet 35 may have a transverse component of non-zero transverse magnetic field strength and transverse to the external magnetic field B₀. This transverse component of the magnetic field may have a gradient in the shuttling direction D2. In addition or alternatively, the magnetic field of the at least one magnet 35 may have a parallel component of non-zero parallel magnetic field strength and parallel to the external magnetic field B₀. This parallel component of the magnetic field may have a gradient in the shuttling direction D2.

This enables the magnetic field acting on the one or more qubits, when the one or more qubits are trapped in a potential well in the quantum well 69 where the magnetic field strength is non-zero. With the inhomogeneous magnetic field of the at least one magnet 35, the EDSR (see above) may be used to rotate the one or more spins of the one or more qubits.

As shown FIGS. 3A-D, the at least one magnet 35 may comprise a first magnet 35-1 and a second magnet 35-2. An example of the first magnet 35-1 is a first micromagnet. An example of the second magnet 35-2 is a second micromagnet.

The first magnet 35-1 may be arranged at the first conveyor gate assembly 50b1. The first magnet 35-1 may be arranged at a distance from the interface 25. A first magnetic field of the first magnet 39-1, which may be inhomogeneous, has a first magnetic field strength (having a longitudinal component and/or a transverse component, as described above) that has a non-zero value at a first portion 69-1 of the quantum well 69. In one aspect, the first magnetic field strength substantially vanishes at the interface 25.

The second magnet 35-2 may arranged at the first conveyor gate assembly 50b1. The second magnet 35-2 may be arranged in a vicinity of the interface 25. In one aspect, the second magnet 35-2 may be arranged at the first conveyor gate assembly 50b1 and the second conveyor gate assembly 50b2. In other words, the second magnet 35-2 may extend across the interface 25 in the shuttling direction (or longitudinal direction) D2.

A second magnetic field of the second magnet 39-2, which may be inhomogeneous, has a second magnetic field strength (having a longitudinal component and/or a transverse component, as described above) that has a non-zero value at a second portion 69-2 of the quantum well 69. The second portion 69-2 may be located in the vicinity of the interface 25. In one aspect, the second portion 69-2 of the quantum well 69 may be located on both sides of the interface 25 along the shuttling direction (or longitudinal direction) D2. The second magnetic field strength may have a non-zero value at the interface 25.

In another aspect of the disclosure, the manipulation zone 20 may comprise solely the first magnet 35-1 or solely the second magnet 35-2.

In a further aspect of the disclosure, the manipulation zone 20 may comprise the top gate 50d (see FIGS. 3C and 3D). The top gate 50d may extend in the lateral (transverse) direction D3. The top gate may extend in the shuttling direction (or longitudinal direction) D2. The top gate 50d may cover at least part of the first path 451 and/or the second path 452. In one aspect, at least in the lateral (transverse) direction D3, the top gate 50d completely covers the first path 451 and/or the second path 452.

In yet another aspect of the disclosure, the top gate electrode 50d may be arranged above the conveyor gates (or finger gates) 50b with a dielectric or insulating layer 67 arranged therebetween (see FIGS. 3C and 3D). The dielectric or insulating layer 67 may be partially arranged on the dielectric or insulating layer 60 (see FIGS. 3C, 3D). Portions of the dielectric or insulating layer 67, which are arranged between the conveyor gates 50b, may be arranged on the dielectric or insulating layer 60 (see FIGS. 3C, 3D). The dielectric or insulating layer 67 may be structured, e.g., segmented or profiled, in the shuttling direction D2 (see FIG. 3D). The dielectric or insulating layer 67 insulates the conveyor gates 50b that belong to different ones of the subsets 50b-1, 50b-2, 50b-3, 50b-4 from each other. In one aspect of the disclosure, the dielectric or insulating layers 60 and 67 are a single dielectric or insulating layer 60, 67, in which the conveyor gates 50b are embedded.

The top gate 50d may be applied with a constant voltage. In a further aspect, the voltage applied to the top gate 50d may be modified on the one or more actions on the one or more qubits. For example, the voltage applied to the top gate 50d may be modified for shuttling the one or more qubits, for initializing the one or more qubits, for reading out of the one or more qubits, for manipulating the one or more qubits. In another example, the voltage applied to the top gate 50d may be modified according to sequence of actions on the one or more qubits, for instance as part of performing an algorithm. In yet a further aspect, the voltage applied to the top gate 50d may be modified periodically or non-periodically. The periodically modifying and/or the non-periodically modifying of the voltage applied to the top gate 50d may depend on the action performed on the one or more qubits. The periodically modifying of the voltage applied to the top gate 50d includes adding a square wave, a sawtooth wave, a superposition of sine waves. The periodically modifying of the voltage applied to the top gate 50d includes adding a stepwise increment to the voltage applied to the top gate 50d. The stepwise increment may depend on the one or more actions performed on the one or more qubits.

In one aspect, the top gate 50d may have a planar top surface (not shown). In another aspect of the disclosure, the top gate 50d may be structured. An example of the structured top gate 50d is a segmented top gate 50d (see FIG. 3D) and/or a top gate 50d with a surface profile (or profiled top gate). As shown in FIG. 3D, the top gate 50d may be structured, e.g., segmented and/or profiled, along the shuttling direction (or longitudinal direction) D2. Additionally or alternatively to the longitudinal structuring, the top gate 50d may be structured, e.g., segmented and/or profiled, along the lateral direction (or transvers direction) D3. In the aspect shown in FIG. 3D, the top gate 50d comprises a plurality of electrodes 50d-1, 50d-2, . . . , 50d-12.

The top gate 50d enables increasing the conveyor gate pitch between the conveyor gates 50b whilst maintaining the ability to shuttle the one or more qubits along the at least one path 45. Furthermore, the structured, e.g., segmented, top gate 50d shown in FIG. 3D enables adjusting or tuning the Rabi frequency of the EDSR, generated by the magnetic field of the at least one magnet 35 and the applied AC electric field, by applying one or more adjustment voltages to one or more of the plurality of electrodes 50d-1, 50d-2, . . . , 50d-12 of the top gate 50d (see below).

In an aspect of the disclosure, the at least one surface 14 may further comprise a back surface 142. The at least one back gate 50c may be arranged on the back surface 142 of the semiconductor heterostructure 12 opposite the top surface 141 (see FIG. 3D). The back surface 142 may be arranged at a bottom of the semiconductor heterostructure. The back surface 142 may be arranged opposite the top surface 141. The back surface 142 may be a surface of the layer of silicon dioxide 62 (described above).

The at least one back gate 50c may extend along the shuttling direction (or longitudinal direction) D2. The at least one back gate 50c may further extend laterally (or transversely to the at least one path 45). For example, the at least one back gate 50c may further extend along the lateral (or transverse) direction D3 transverse to the at least one path 45. The at least one back gate 50c may overlap with or intersect the screening gates 50a in the lateral direction D3. The at least one back gate 50c may be arranged opposite the screening gates 50a. A voltage may be applied to the at least one back gate 50c to provide an electrical potential to modify the confinement at the quantum well 69.

In one aspect of the disclosure, the at least one back gate 50c may be structured, e.g., segmented and/or profiled, along the shuttling direction D2. In another aspect of the disclosure, the at least one back gate 50c may be structured, e.g., segmented and/or profiled, along the lateral direction D3 transverse to the at least one path 45. In a yet a further aspect of the disclosure, the at least one back gate may be structured along the shuttling direction D2 and the lateral direction D3.

As shown in FIGS. 3B-D, the screening gates 50a and the conveyor gates 50b are separated by the insulating or dielectric layer 60. As explained above, the insulating or dielectric layer 60 may be planarized during manufacturing before arranging the conveyor gates 50b on the insulating or dielectric layer 60. The four electrode subsets of the conveyor gates 50b may be separated by further insulating or dielectric layers or material (not shown). Furthermore, a dielectric or insulating layer 66 may be provided on the semiconductor heterostructure 12 (see FIG. 3B-3D). The insulating or dielectric layer 66 separates the screening gates 50a and the semiconductor heterostructure 12. The screening gates 50a may be provided on the insulating layer 66.

The manipulation zone 20 is configured to manipulate the one or more qubits at the least one magnet 35. During the operation of the quantum processor 10, the manipulation zone 20 will be used to manipulate the one or more qubits. The manipulating may be a a single-qubit action or two-qubit action.

FIG. 3E shows a line cut of a temporal sequence (in four panels I, II, III, IV) of a simulation of an evolution of a potential energy landscape generated by applying voltages to the gate electrodes 50 to move two qubits (represented by the filled circles) towards the interface 25 (indicated by the dashed vertical line) and of lowering the tunnel barrier between the two qubits to achieve an exchange interaction J. The detuning between the confinement potentials for the two qubits is zero in this simulation. The x-axis represents the distance from the interface 25 along the shuttling direction D2. The y-axis represents the potential energy (or confinement energy). The horizontal bars above the potential energy represent relative values of the voltages applied to the conveyor gates 50b at the interface 25.

Using two shuttling elements 16 that meet an the interface 25 enables the independent control of both the distance between the two qubits at the interface and the tunnel barrier between the two qubits. Effectively, an independent control of tunnel barrier height and width results in lower charge noise sensitivity and an increased robustness against disorder. Compared to multi-quantum dot arrays, control is significantly simplified since high outer barriers are achieved automatically during shuttling and only the interdot barrier needs to be controlled precisely. The actual gate operation is based on adiabatically turning on the exchange interaction J which shifts the energy levels of the antiparallel spin states in such a way that they acquire additional phases. After accumulating phases for t=πh/J(t), subsequent single-qubit gates allow the implementation of a CPHASE gate.

In one aspect of the disclosure, the single-qubit action is the rotating of the one or more qubits by means of the EDSR, which is based on moving, by applying the AC electric field, one or more wave functions of the one or more electrons (or holes) trapped (confined) in the potential well that is located in the first portion 69-1 of the quantum well 69, where the first magnetic field strength of the inhomogeneous first magnetic field of the first magnet 35-1 is non-zero. The AC electric field may be generated by a microwave signal, e.g. applied to one or more of the conveyor gates 50b. The resulting Rabi frequency is given by Ω=(gμ_{B}E₀/2κ)(dB_{⊥}/dx), where g is the g-factor, μ_{B} the Bohr magneton, E₀ an amplitude of the AC electric field, dB_{⊥}/dx a gradient in the shuttling direction D2 (represented by x) of the magnetic field of the at least one magnet 35 transverse to the external magnetic field B₀ (the transverse component of the magnetic field of the at least one magnet 35 described above), and κ the curvature of the confining potential well, which in the first approximation may be described by a parabolic potential (½)κx² around a minimum of the confining potential well at x=0. The strength of the confining potential and the orbital level splitting are determined by the curvature κ. From the equation for the Rabi frequency Ω it can be seen that a change Δκ in the curvature κ of the confining potential well results in a change ΔΩ in the Rabi frequency Ω given by ΔΩ=−(Ω/κ)Δκ.

In one aspect of the disclosure, the one or more qubits are moved (shuttled) in an oscillatory manner at a location of a maximum of the gradient in the shuttling direction D2 of the magnetic field of the at least one magnet 35 transverse to the external magnetic field B₀. For high fidelity single-qubit gates, an amplitude of the oscillatory moving of the one or more qubits is estimated to be on the order of 20 nm, which is significantly larger than for conventional EDSR, where the amplitudes are on the order of a few picometers. The higher amplitude allows for using weaker magnetic field gradients, which in turn increases the overall robustness against charge noise.

The change Δκ in the curvature κ of the confining potential may be generated by applying one or more adjustment voltages to one or more of the plurality of electrodes 50d-1, 50d-2, . . . , 50d-12 of the top gate 50d.

We consider an adjustment voltage ΔV applied to a single electrode (termed hereafter “tuning gate”) of the plurality of electrodes 50d-1, 50d-2, . . . , 50d-12 of the top gate 50d. This tuning gate may be located at the first portion 69-1 or at the second portion 69-2 of the quantum well 69. The tuning gate may be located in the vicinity of the potential well in which the one or more qubits are trapped. For instance, in the case of FIG. 3D, the tuning gate may be one of the electrodes 50d-2, 50d-3, 50d-6, 50d-7, or 50-d8 of the top gate 50d, but is not limited thereto. If the potential well in which the one or more qubits are trapped is located in the first portion 69-1 or the second portion 69-2, the Rabi frequency for rotating the one or more qubits may be changed. The adjustment voltage ΔV applied to the tuning gate results in an adjustment potential that may be modelled as a potential generated by a dipole line oriented perpendicular to the shuttling direction D2 (i.e., oriented in the lateral or transverse direction D3) and pointing in the stacking direction D1: φ_{adj}=φ_{adj,0}(d²/(d²+x²), where φ_{adj,0} is a prefactor proportional to the adjustment voltage ΔV applied to the tuning gate relative to the voltages applied to plurality of gate electrodes 50 and the width of the tuning gate, x is the position along the shuttling direction D2, and d is a distance between the dipole line and the at least one path 45. Furthermore, the potential well in which the one or more qubits are trapped may be modelled as φₛ=φₛ₀cos(k(x−x₀(t))), where k=2π/λ, λ is the spatial period, φₛ₀ is a prefactor determined by the voltages applied to the conveyor gates 50b, and x₀ is a position along the shuttling direction D2 of the minimum of the potential well in which the one or more qubits are trapped.

In order to maintain the one or more qubits trapped in the potential well, there is an upper bound for the adjustment voltage ΔV applied to the tuning gate. The upper bound for the adjustment voltage ΔV may correspond to an upper bound for the prefactor given by |φ_{adj,0}|<(4.8 d/λ)|φₛ₀|. The adjustability or tunability of the Rabi frequency Ω is quantified by the ratio of the confining strengths (or curvatures) of the adjustment potential and the shuttling potential, i.e., by the ratio of the second derivative d²φ_{adj}/dx² and d²φₛ/dx². The upper bound for the adjustment voltage estimated above leads to an adjustability (or adjustment range) or tunability (or tuning range) of the Rabi frequency Ω of 0.25 d/λ. For typical values of d=50 nm and λ=300 nm, the tuning range of the confinement strength is thus by a factor 1.5 larger than the confinement due to the shuttling potential φₛ alone. For a deconfining adjustment (or deconfining tuning) of the Rabi frequency Ω, it is advisable to remain below the upper bound in order to retain a shape of the potential well that has a harmonic minimum. Further considerations lead to the conclusion that an amplitude of the displacement of the one or more qubits in the inhomogeneous magnetic field are bound by approximately 15 nm in order to ensure that the potential well may be approximated by the first order quadratic potential that is described by the curvature κ.

Examples of the adjustment potential φ_{adj} as well as the resulting sum of the adjustment potential φ_{adj} and the shuttling potential φₛ (which may also be referred to as “adjusted potential well”) are shown in the upper panel of FIG. 4, where values of d=50 nm and λ=300 nm were chosen. Two examples of the adjusted potential well are shown with the adjustment voltage weakening the confinement (“deconfining”) or strengthening the confinement (“confining”). The corresponding non-adjusted potential well is shown with the adjustment voltage not changing the confinement (“unperturbed”). The solid lines indicate the adjusted potential well. The dashed lines indicate the adjustment or tuning potential φ_{adj}. A Gaussian charge density indicating the spatial distribution of the one or more qubits that are trapped in the potential well is shown. As explained above, the adjusted potential well results in the adjusted Rabi frequency Ω.

In another aspect of the disclosure, in the case of the presence of a non-zero gradient dB_{∥}/dx in the shuttling direction D2 of a magnetic field of the at least one magnet 35 parallel to the external magnetic field B₀ (the parallel component of the magnetic field of the at least one magnet 35 described above), the splitting of the spin-dependent energy levels by means of the external magnetic field B₀ may be adjusted by changing an average position of the minimum of the potential well by means of another one of the adjustment potential. This adjustment potential may be generated by applying the adjustment voltage ΔV to one or more of the electrodes 50d-1, 50d-2, . . . , 50d-12 of the top gate 50d. The applying of the adjustment voltage may result in the changing of an average position of the one or more qubits trapped in the potential well.

We consider adjustment voltages ΔV applied to two electrodes (“tuning gates”) of the one or more of the electrodes 50d-1, 50d-2, ..., 50d-12 of the top gate 50d. The two tuning gates may be located in the vicinity of the potential well in which the one or more qubits are trapped. For instance, in the case of FIG. 3D, the two tuning gates may be chosen from the electrodes 50d-2, 50d-3, 50d-6, 50d-7, or 50-d8 of the top gate 50d, but are not limited thereto. In one aspect, the two tuning gates may be located around the position of the potential well. For example, the two tuning gates may be located at a distance of the minimum of the potential well along the shuttling direction D2. The two tuning gates may comprise a first tuning gate located in FIG. 3D on the left of the minimum of the potential well, and a second tuning gate located in FIG. 3D on the right of the minimum of the potential well. If the potential well in which the one or more qubits are trapped is located in the first portion 69-1 or the second portion 69-2, the afore-mentioned choice of the two tuning gates will result in a changed average position of the potential well, e.g., the minimum of the potential well, in which the one or more qubits are trapped. The changed average position of the potential well results in a changed magnetic field generating the spin-dependent energy levels B₀+ΔB₀ with ΔB₀=(dB_{∥}/dx)Δx. As a result of the changed magnetic field the resonance frequency v=(gμ_{B}/h)B₀ changes by Δv=(gμ_{B}/h)ΔB₀.

One example of the adjustment potential φ_{adj} as well as the adjusted potential well are shown in the lower panel of FIG. 4, where values of d=50 nm and φ=300 nm were chosen. An example of the adjusted potential well is shown with the adjustment voltage changing the position of the minimum of the potential well (“shifting”). The corresponding non-adjusted potential well is shown with the adjustment voltage not changing the position of the minimum of the potential well (“unperturbed”). The solid lines indicate the adjusted or non-adjusted potential well. The dashed lines indicate the adjustment or tuning potential (adj, which is here the sum of potentials generated by dipole lines with opposing values of the adjustment voltages applied thereto. Furthermore, a Gaussian charge density indicating the spatial distribution of the one or more qubits that are trapped in the potential well is shown. As explained above, the adjusted potential well results in the adjusted resonance frequency.

The considerations regarding upper bounds of the adjustment voltages similarly apply in the case of adjusting the resonance frequency in order not to compromise shuttling of the one or more qubits. Similar assumptions (see above) lead to maximal shifts of the sum of minimum of the potential well and the displacement of the one or more qubits trapped within the potential well by about 15 nm.

In a further aspect of the disclosure, the potential barrier (or tunnel barrier) and the detuning at the interface 25 may be adjusted. The adjustment voltages AV may be applied to one or more of the electrodes 50d-1, 50d-2, . . . , 50d-12 of the top gate 50d. For instance, one of the adjustment voltages ΔV may be applied to the electrode 50d-8 to increase or decrease the tunnel coupling across the potential barrier (tunnel barrier). Others of the adjustment voltages ΔV may be applied to the electrodes 50d-7 and 50d-9 to change the detuning between the at least one first stationary potential well and the at least one second stationary potential well.

In another aspect of the disclosure, the adjusting voltages may be applied to the conveyor gates 50b instead of to one or or more of the electrodes 50d-1, 50d-2, . . . , 50d-12 of the top gate 50d. In the aspects of the disclosure shown in FIGS. 3B and 3C, the conveyor gates 50b have electrode subsets 50b1-1, 50b1-2, 50b1-3, 50b1-4, 50b2-1, 50b2-2, 50b2-3, 50b2-4 that are independently supplied with voltages. In the aspect shown in FIG. 3D, at least three electrodes belonging to the electrode subsets 50b1-2, 50b1-3, 50b1-4 are located at the first portion 69-1 of the quantum well 69. Furthermore, at least three electrodes belonging to the electrode subsets 50b1-3, 50b1-4, 50b2-1 are located at the second portion 69-2 of the quantum well 69. One or more of the electrode subsets may be supplied with an AC voltage for shuttling the potential wells and with adjustment voltages (DC voltages) for adjusting the manipulation parameters in a similar manner as when the adjustment voltages are applied to the electrodes 50d-1, 50d-2, . . . , 50d-12 of the top gate 50d.

The foregoing examples of adjusting the Rabi frequency Ω, the resonance frequency v, or the exchange coupling J explain how the manipulation fidelity F_{M} may be increased by adjusting parameters relating to the manipulating of the one or more qubits (or “manipulation parameters”). The manipulation parameters comprise the Rabi frequency Ω, the resonance frequency v, and the exchange coupling J. The adjusting of the manipulation parameters enables overcoming the effect of fidelity-reducing loci or disorder in the quantum well 69. The fidelity-reducing locus 70 may be the result of, for example, a manufacturing impurity, a manufacturing defect, a charge defect, a crystal defect, and/or a locally reduced valley splitting. The fidelity reducing locus 70 may further be the result of the non-zero magnetic field strength, parallel to the external magnetic field B₀, of the at least one magnet 35, which may affect the Rabi frequency 22 (as can be seen from, e.g., formula (2) in Kloeffel and Loss, Prospects for Spin-Based Quantum Computing, 2012). When it is determined that the manipulation fidelity F_{M} does not meet the requirements for a reliable operation of the quantum processor 10, adjusting one or more of the manipulation parameters enables increasing the manipulation fidelity F_{M}.

1. A manipulation zone for a quantum processor comprising a plurality of gate electrodes arranged on a semiconductor heterostructure, wherein
the plurality of gate electrodes comprises a first finger gate assembly arranged at a first path in the semiconductor heterostructure and a second finger gate assembly arranged at a second path in the semiconductor heterostructure,
the first path and the second path meet at an interface;
the first finger gate assembly and the second finger gate assembly are configured to be supplied with at least one voltage V, to move along the first path and/or the second path at least one qubit, and/or to manipulate a current spin state of the at least one qubit located at the first path and/or the second path.

2. The manipulation zone of claim 1, wherein the manipulation zone (20) further comprises at least one magnet.

3. The manipulation zone of claim 2, wherein the at least one magnet is arranged at the interface.

4. The manipulation zone of claim 2, wherein the at least one magnet is arranged at a distance from the interface.

5. The manipulation zone of claim 1, wherein the semiconductor heterostructure is made from semiconductor materials providing spin-orbit coupling

6. The manipulation zone of claim 1, wherein at least one of the first finger gate assembly and the second finger gate assembly comprises a plurality of electrode subsets.

7. The manipulation zone of claim 6, wherein ones of the plurality of electrode subsets are electrically disconnected from each other.

8. The manipulation zone of claim 6, wherein ones of the plurality of electrode subsets have a dielectric or insulating layer arranged between each other.

9. The manipulation zone of claim 1, further comprising a top gate arranged above the first finger gate assembly and/or the second finger gate assembly.

10. The manipulation zone of claim 9, wherein the top gate is structured in a longitudinal direction.

11. The manipulation zone of claim 1, wherein a dielectric or insulating layer is arranged between the semiconductor heterostructure and the plurality of gate electrodes.

12. The manipulation zone of claim 1, wherein ones of the plurality of gate electrodes have a dielectric or insulating layer arranged between each other.

13. The manipulation zone of claim 1, wherein the plurality of gate electrodes is arranged on at least one surface of semiconductor heterostructure.

14. A system comprising the manipulation according to claim 1 and a magnet providing an external magnetic field B₀.

15. A method of manipulating at least one qubit located at a first path in a semiconductor heterostructure and/or a second path in the semiconductor heterostructure, the first path and the second path meeting at an interface, and the semiconductor heterostructure comprising a plurality of gate electrodes arranged thereon, the method comprising the steps of
providing an external magnetic field B₀;
changing a current spin state of the at least one qubit by displacing the at least one qubit along the first path and/or the second path by means of an AC electric field applied to a gate electrode of the plurality of gate electrodes, or by irradiating the at least one qubit with electromagnetic radiation.

16. The method of claim 15, further comprising adjusting a Rabi frequency or a resonance frequency relating to the changing of the current spin state of the at least one qubit.

17. The method of claim 15, further comprising changing a tunnel barrier at the interface.

18. The method of claim 15, further comprising changing a detuning between two qubits confined on either side of the interface.
